(19) United States
(12) Patent Application Publication
(10) Pub. No.: US 2010/0046171 A1
(43) Pub. Date: Feb. 25, 2010

(54) FASTENING MEMBER

(75) Inventors: Cheng-Lung Chen, Shijhih City (TW); Ting-Lun Liao, Shijhih City (TW)

Correspondence Address: APEX JURIS, PLLC, 12733 LAKE CITY WAY NORTHEAST, SEATTLE, WA, 98125, US

(73) Assignee: MICRO-STAR INTERNATIONAL CO., LTD., Jung-He City (TW)

(21) Appl. No.: 12/330,726

(22) Filed: Dec. 9, 2008

(30) Foreign Application Priority Data
Aug. 20, 2008 (TW) 097214959

(51) Int. Cl. H05K 7/20

(52) U.S. Cl. 361/709

(57) ABSTRACT

A fastening member for fastening a peripheral device in an electronic device casing and performing heat exchange with the peripheral device is presented. The fastening member includes a supporting plate and a pair of side plates. This pair of side plates is respectively disposed on two sides of the supporting plate to support the peripheral device. The side plates can be fastened to the electronic device casing. The supporting plate has a plurality of heat-conductive connecting pieces in contact with the casing for transferring heat generated by the peripheral device to the electronic device casing, so as to perform heat exchange.

### CROSS-REFERENCE TO RELATED APPLICATIONS

This non-provisional application claims priority under 35 U.S.C. §119(a) on Patent Application No(s). 097214959 filed in Taiwan, R.O.C. on Aug. 20, 2008 the entire contents of which are hereby incorporated by reference.

### BACKGROUND OF THE INVENTION

1. Field of Invention

The present invention relates to a fastening member, and more particularly to a fastening member capable of performing heat exchange.

2. Related Art

Currently, as operation of heat generating units such as central processing unit (CPU) and a random access memory (RAM) in an electronic device commercially available on the market is becoming faster and faster, the amount of data processed per unit time is also multiplying. Therefore, in the case of long time use, the operating ambient temperature inside the electronic device often becomes excessively high, thereby affecting normal operation of the electronic device and increasing failure and damage probabilities of the electronic device.

In order to prevent the electronic device from being under an abnormal operating ambient temperature due to heat generated by the heat generating units, a fan is additionally mounted on the electronic device casing and the heat generating units are then connected to heatsink pipes, such that the heat generated by the heat generating units is transferred to the fan via the heatsink pipes and then dissipated to the outside of the electronic device by the operation of the fan, thereby avoiding excessively hot conditions.

However, a hard disk drive (HDD) heatsink of a notebook in the prior art has the following disadvantages. An HDD is generally mounted at a corner within the electronic device casing. When only heat pipes are used for heat dissipation, the efficiency is lower than those of the RAM and CPU. Therefore, additional modules such as heatsink fins and fans are usually mounted on the housing of the HDD to increase the heat dissipation efficiency. However, since the space within the notebook is limited, the volume of the notebook must be increased in order to accommodate additional HDD heatsink modules. Therefore, disposition of additional HDD heatsink modules not only causes the assembly and disassembly to be more difficult, but also increases the assembly cost in labor force and man-hours. Moreover, an additional cost is also needed for fabricating the HDD heatsink modules.

### SUMMARY OF THE INVENTION

In view of the above, in a conventional hard disk drive (HDD) heatsink, if additional modules such as heatsink fins and fans are still mounted on the housing of the HDD when the space within the notebook is limited, the space is quite crowded. Meanwhile, the notebook has increased weight and thus loses its convenience in carrying about. Moreover, more time and cost are required in assembly and fabrication.

Accordingly, the present invention is directed to a fastening member, which is used for fastening a peripheral device in an electronic device casing and performing heat exchange with the peripheral device. The fastening member includes a supporting plate and a pair of side plates. The side plates are respectively disposed on two sides of the supporting plate. The supporting plate is fastened to the electronic device casing via the side plates. The supporting plate has an inner surface and an outer surface. The inner surface and the side plates constitute a supporting range for supporting the peripheral device. The outer surface is disposed with a plurality of heat-conductive connecting pieces, and the heat-conductive connecting pieces are in contact with the electronic device casing, such that the heat generated by the peripheral device is transferred to the electronic device casing via the supporting plate.

The present invention has the following efficacies. The peripheral device is disposed within the supporting range constituted by the inner surface of the supporting plate and the side plates respectively disposed on two sides of the supporting plate, and the supporting plate is fastened within the electronic device casing via the side plates. The outer surface of the supporting plate is disposed with a plurality of heat-conductive connecting pieces, and the heat-conductive connecting pieces are in contact with the electronic device casing, such that the heat generated by the peripheral device is transferred to the electronic device casing via the supporting plate by the heat-conductive connecting pieces, thereby achieving heat dissipation of the peripheral device.

### BRIEF DESCRIPTION OF THE DRAWINGS

The present invention will become more fully understood from the detailed description given herein below for illustration only, and thus are not limitative of the present invention, and wherein:

FIG. 1 is a schematic three-dimensional view of the present invention;

FIG. 2 is a schematic exploded view of the present invention;

FIG. 3 is a schematic three-dimensional view of the present invention;

FIG. 4 is a schematic three-dimensional view of the present invention;

FIG. 5 is a schematic assembly view of the present invention;

FIG. 6A is a schematic cross-sectional view of the present invention; and

FIG. 6B is a schematic cross-sectional view of the present invention.

### DETAILED DESCRIPTION OF THE INVENTION

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description. The following embodiments are intended to describe the present invention in further detail, and are not intended to limit the scope of the present invention in any way.

The fastening member of the present invention is, but not limited to, applicable to an electronic device, such as a notebook, a desktop computer, a tablet personal computer, and an ultra mobile personal computer (UMPC), for dissipating heat of a peripheral device through heat exchange.

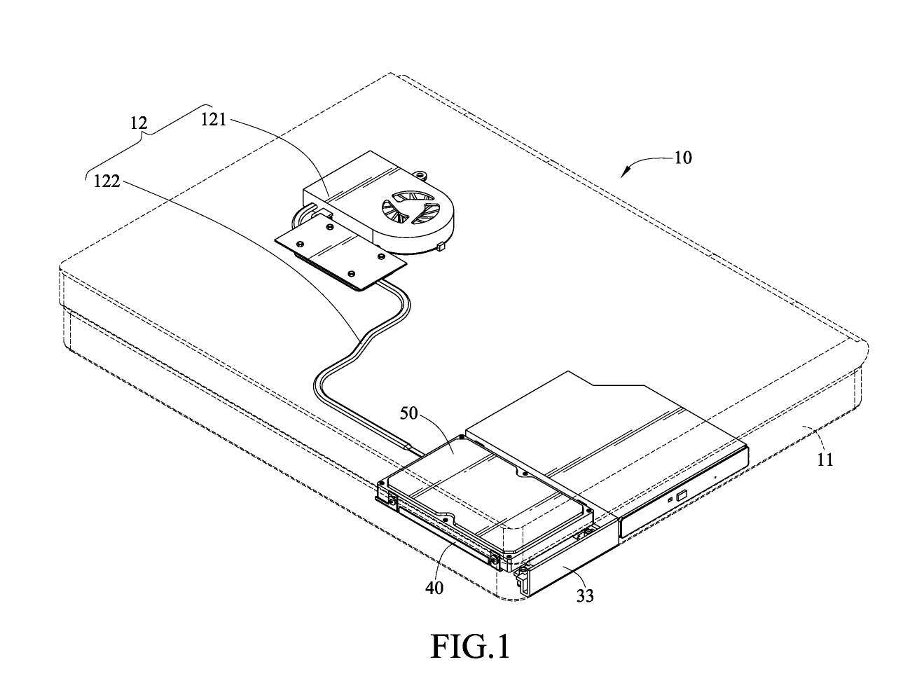

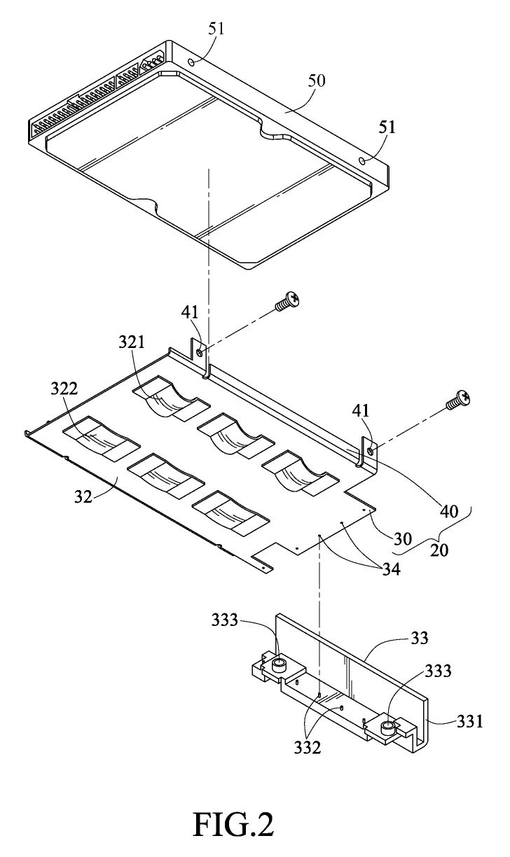

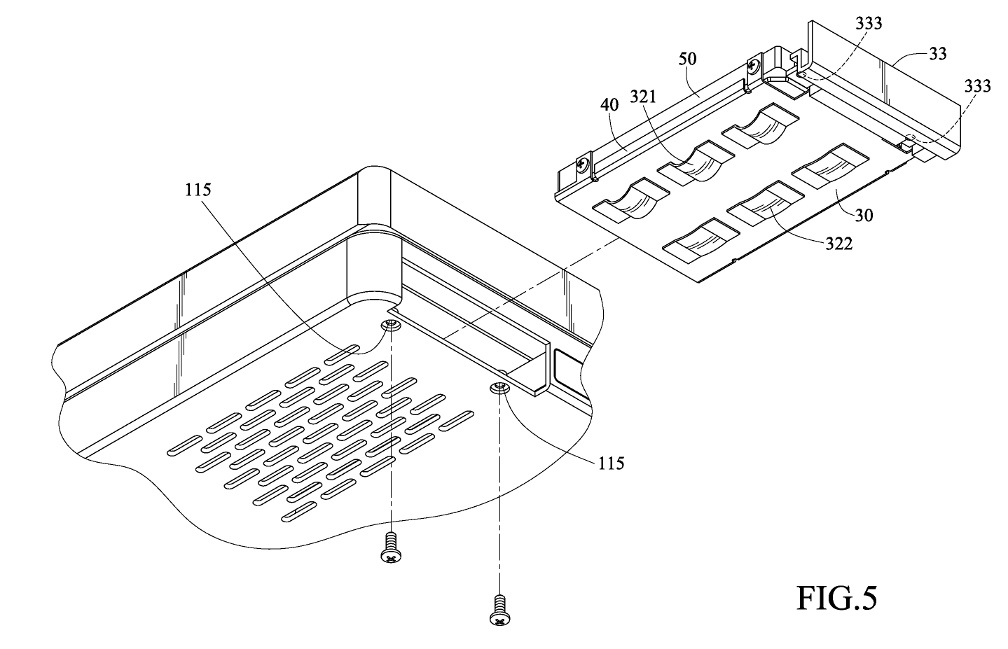

FIGS. 1 to 5 are schematic views of the present invention. Referring FIGS. 1 to 5, a fastening member 20 of the present invention includes a supporting plate 30 and a pair of side plates 40.

A notebook 10 has an electronic device casing 11 and a liquid crystal display (not shown in the figures). In the electronic device casing 11, a lower surface and a plurality of wall plates perpendicular to the lower surface constitute a plurality of accommodating spaces of different sizes for configuration of different peripheral devices 50. The peripheral device 50 may be a hard disk drive (HDD), a Bluetooth module, an optical disk drive, and the like. In this embodiment, illustration is given by taking the HDD as an example.

The electronic device casing 11 has a heatsink 12 therein. The heatsink 12 has a fan 121 and a fin-tube 122. The fin-tube 122 is distributed within the notebook 10 to contact electronic elements (not shown) such as central process unit (CPU) and random access memory (RAM), such that the heat generated by the electronic elements is transferred to the fan 121, and the heat is dissipated out of the electronic device casing 11 by the fan 121. However, such electronic elements are not technical features of the present invention to be emphasized, and thus, the details will not be described in detail herein.

The supporting plate 30 is connected to a connection base 33. The connection base 33 has a holding portion 331, a plurality of convex points 332, and two locking holes 333. The supporting plate 30 is provided with a pair of corresponding through holes 34 at positions corresponding to the convex points 332. After the convex points 332 of the supporting plate 30 are penetrated through the through holes 34, the upsides of the convex points 332 are melted by welding or heat fusing, such that diameters of the convex points 332 after cooling are larger than those of the through holes 34, thereby fastening the supporting plate 30 to the connection base 33. The electronic device casing 11 is respectively provided with through holes 115 at positions corresponding to the two locking holes 333. The connection base 33 can be fastened within the electronic device casing 11 together with the supporting plate 30 by penetrating screws through the locking holes 333 of the connection base 33 and the through holes 115. The holding portion 331 facilitates a user to hold the fastening member 20. The holding portion 331 can be tightly coupled to the electronic device casing 11 when the fastening member 20 is disposed within the electronic device casing 11.

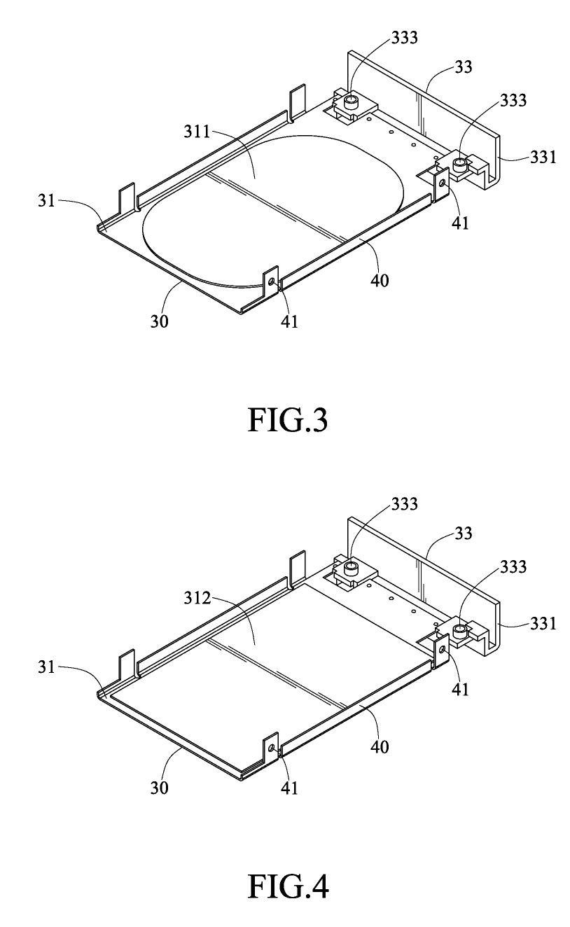

The supporting plate 30 has an inner surface 31 and an outer surface 32. The side plates 40 are respectively disposed on two sides of the supporting plate 30. The peripheral device 50 is disposed within a supporting range constituted by the supporting plate 30 and the side plates 40, and is in contact with the inner surface 31. The supporting plate 30 and the side plates 40 are both made of a heat-conductive material, such as aluminum and an alloy. The peripheral device 50 is provided with locking holes 51 on one side thereof. The side plates 40 are provided with through holes 41 corresponding to the locking holes 51. Screws are penetrated through the through holes 41 and locked into the locking holes 51, so as to fasten the peripheral device 50 to the supporting plate 30. A layer of heatsink paste 311 (as shown in FIG. 3) is coated, or a heat transfer pad 312 (as shown in FIG. 4) is disposed, between the inner surface 31 and the peripheral device 50. The heat generated by the peripheral device 50 is uniformly transferred to the inner surface 31 via the heatsink paste 311 or the heat transfer pad 312. If the heatsink paste 311 is not coated or the heat transfer pad 312 is not disposed to serve as a heat transfer medium, the housing of the peripheral device 50 cannot be completely adhered to the inner surface 31 when it contacts the inner surface, resulting in heat accumulation in some places and thus causing the peripheral device 50 to be excessively hot due to excessively high temperature. The outer surface 32 is disposed with a plurality of heat-conductive connecting pieces 321 and heat-conductive connecting pieces 322 extending from the outer surface 32. The heat-conductive connecting pieces 321 and 322 are designed as blade springs, and the curvature of the heat-conductive connecting pieces 321 is greater than that of the heat-conductive connecting pieces 322. Besides being divided into three sections as shown in the schematic views, the heat-conductive connecting pieces 321 and the heat-conductive connecting pieces 322 may also be designed integrally.

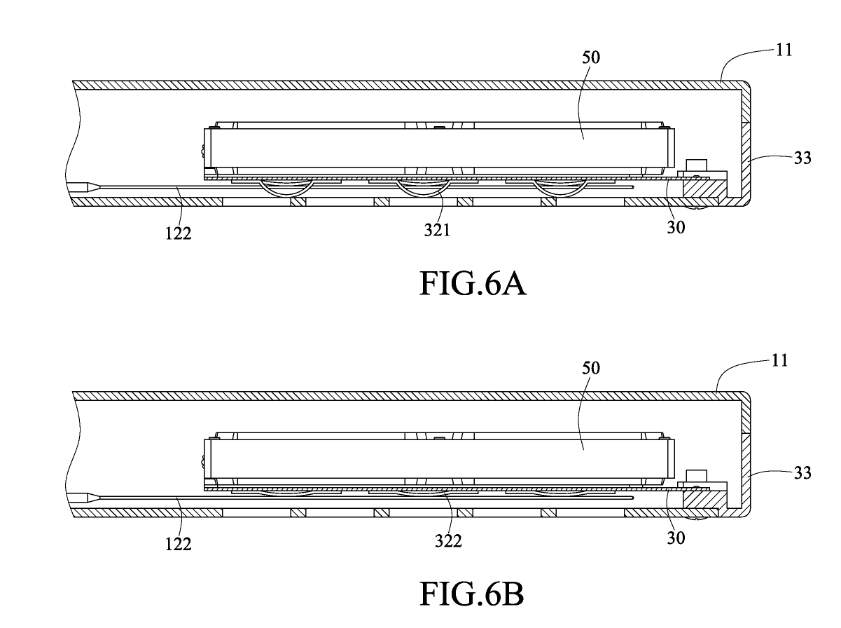

Referring to FIGS. 6A and 6B, schematic views of two sides of the heat-conductive connecting pieces 321 and 322 of the present invention are shown respectively. When the fastening member 20 is mounted to the electronic device casing 11, the heat-conductive connecting pieces 321 can contact the electronic device casing 11 due to the large curvature thereof, and the heat-conductive connecting pieces 322 do not contact the electronic device casing 11 due to the small curvature thereof, and thus the heat-conductive connecting pieces 322 are in contact with the fin-tube 122. Since the heat-conductive connecting pieces 321 and 322 are blade springs, they can respectively closely contact the electronic device casing 11 and the fin-tube 122. When the electronic device casing 11 is made of a heat-conductive material, after the heat generated by the peripheral device 50 is transferred to the supporting plate 30 via the heatsink paste 311 or the heat transfer pad 312, the heat not only can be transferred to the electronic device casing 11 via the heat-conductive connecting pieces 321 and then dissipated from the electronic device casing 11, but also can be transferred to the fin-tube 122 via the heat-conductive connecting pieces 322 and then dissipated by the fan 121. If the electronic device casing 11 is not made of a heat-conductive material, the heat generated by the peripheral device 50 can also be transferred to the fin-tube 122 via the heat-conductive connecting pieces 322 and then dissipated by the fan 121, thereby achieving the heat dissipation of the peripheral device 50.

The fastening member of the present invention has the following efficacies. The peripheral device is disposed in the supporting range constituted by the supporting plate and the side plates and is in contact with the inner surface of the supporting plate, and the outer surface of the supporting plate is disposed with heat-conductive connecting pieces in contact with the electronic device casing. Therefore, after the heat generated by the peripheral device is transferred to the electronic device casing via the supporting plate and the heat-conductive connecting pieces, the heat dissipation of the peripheral device can be achieved. In such a manner, additional modules such as heatsink fins and fans do not need to be mounted at the peripheral devices. The temperature of the peripheral devices can be effectively lowered via the casing simply by using the heat-conductive connecting pieces. Moreover, the present invention is easily fabricated and conveniently assembled and disassembled, and thus can reduce the assembly cost in labor force and man-hours.

What is claimed is:

1. A fastening member, for fastening a peripheral device in an electronic device casing and performing heat exchange with the peripheral device, comprising:
a supporting plate, having an inner surface and an outer surface, wherein the inner surface is in contact with the peripheral device, the outer surface is disposed with a plurality of heat-conductive connecting pieces, and the heat-conductive connecting pieces are in contact with the electronic device casing, such that heat of the peripheral device is transferred to the electronic device casing via the supporting plate; and
a pair of side plates, respectively disposed on two sides of the supporting plate to constitute a supporting range for mounting the peripheral device, wherein the supporting plate is connected and fastened to the electronic device casing via the pair of side plates.

2. The fastening member according to claim 1, wherein a layer of heatsink paste is coated between the inner surface and the peripheral device.

3. The fastening member according to claim 1, wherein a heat transfer pad is disposed between the inner surface and the peripheral device.

4. The fastening member according to claim 1, wherein the heat-conductive connecting pieces are blade springs extending from the outer surface.

5. The fastening member according to claim 1, wherein the heat-conductive connecting pieces are in contact with a heatsink mounted within the electronic device casing.
